(19) United States
(12) Patent Application Publication
(10) Pub. No.: US 2009/0314556 A1
(43) Pub. Date: Dec. 24, 2009

(54) VEHICLE INTERIOR SOLAR PANELS

(75) Inventor: Daryl Robert Harris, Irvine, CA (US)

Correspondence Address: SNELL & WILMER LLP (OC), 600 ANTON BOULEVARD, SUITE 1400, COSTA MESA, CA, 92626, US

(73) Assignee: Calty Design Research, Inc., Newport Beach, CA (US)

(21) Appl. No.: 12/141,843

(22) Filed: Jun. 18, 2008

(51) Int. Cl. B60K 16/00; H01L 31/042; H02J 7/32

(52) U.S. Cl. 180/65.1; 136/244; 320/101

(57) ABSTRACT

The present invention relates to vehicle interior solar panels and more specifically flexible vehicle interior solar panels. In one embodiment, the present invention is an automobile comprising an instrument panel including an instrument panel top surface, the instrument panel top surface including a portion defining a recessed portion, a first flexible solar panel located within the recessed portion, an energy storage unit connected to the first flexible solar panel and receiving electricity from the first flexible solar panel, and an electronic component connected to the energy storage unit.

### BACKGROUND

1. Field

The present invention relates to vehicle interior solar panels and more specifically to flexible vehicle interior solar panels.

2. Background

With rising energy costs, current automobiles face higher costs of operation. Thus, there have been investigations towards alternative fuel sources which oftentimes can be complex. Developing complex fuel sources can be extremely expensive. Furthermore, some fuel sources can be extremely dangerous, especially in an accident.

Thus, there is a need for relatively inexpensive and reliable energy or fuel sources that are relatively safe in an accident.

### SUMMARY

In one embodiment, the present invention is an automobile comprising an instrument panel including an instrument panel top surface, the instrument panel top surface including a portion defining a recessed portion, a first flexible solar panel located within the recessed portion, an energy storage unit connected to the first flexible solar panel and to receive electricity from the first flexible solar panel, and an electronic component connected to the energy storage unit.

### BRIEF DESCRIPTION OF THE DRAWINGS

The features, objects, and advantages of the present invention will become more apparent from the detailed description set forth below when taken in conjunction with the drawings, wherein:

FIG. 1 is a block diagram of a vehicle interior solar system according to an embodiment of the present invention.

FIG. 2 is a perspective view of an exemplary solar panel embedded into or on a dashboard or an instrument panel of automobile according to an embodiment of the present invention.

FIG. 3 is a cross-sectional view of FIG. 2 along line A-A showing flexible solar panel embedded or placed into instrument panel according to an embodiment of the present invention.

FIG. 4 is a cross-sectional view of FIG. 2 along line A-A showing a translucent thin film placed on top of flexible solar panel such that both layers are within a recessed portion of instrument panel according to an embodiment of the present invention.

FIG. 5 is a block diagram of a vehicle interior solar system according to an embodiment of the present invention.

FIG. 6 is a block diagram of a vehicle interior solar system according to an embodiment of the present invention.

FIG. 7 is a perspective view of an exemplary solar panel embedded into or on a dashboard or an instrument panel of automobile according to an embodiment of the present invention.

FIG. 8 is a cross-sectional view of two solar panels where one is on top of the other according to an embodiment of the present invention.

### DETAILED DESCRIPTION

Apparatus, systems and methods that implement the embodiments of the various features of the present invention will now be described with reference to the drawings. The drawings and the associated descriptions are provided to illustrate some embodiments of the present invention and not to limit the scope of the present invention. Throughout the drawings, reference numbers are re-used to indicate correspondence between referenced elements.

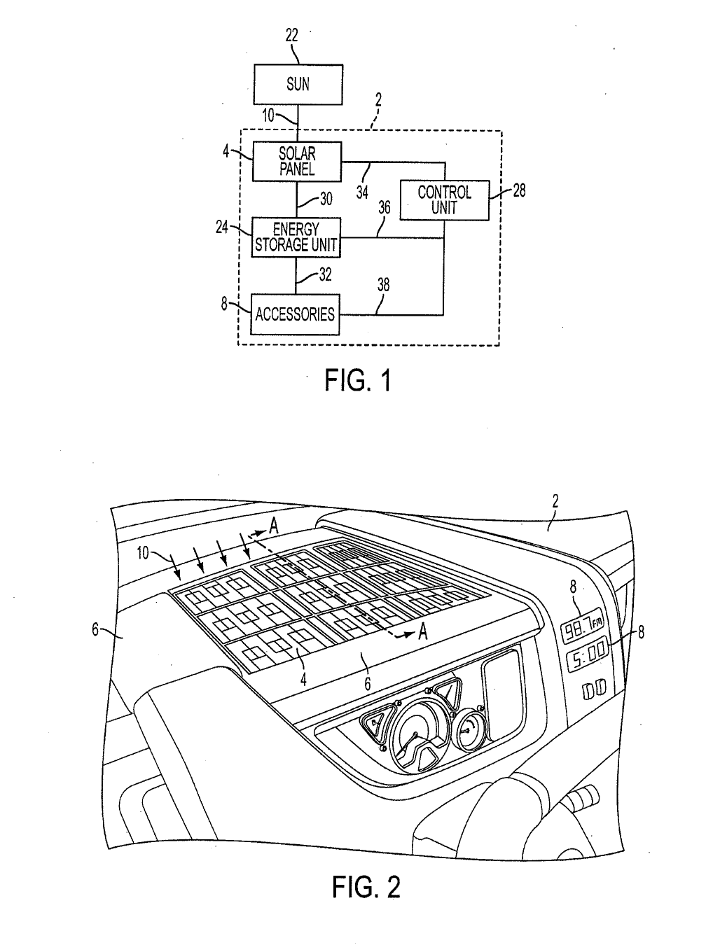

FIG. 1 is a block diagram of a vehicle interior solar system according to an embodiment of the present invention. As seen in FIG. 1, a vehicle 2 (e.g., an automobile) includes a flexible solar panel 4, an energy storage unit 24, a control unit 28, and accessories 8. Vehicle 2 can be, for example, a hybrid car, a car with a combustion engine, a hydrogen fuel cell car, an electric car, a car utilizing ethanol, and/or any other type of conventional or alternative fuel source car.

Solar panel 4 is connected to control unit 28 through connection 34 and energy storage unit 24 through connection 30. Flexible solar panel 4 can receive, for example, rays of light 10 containing solar energy from sun 22, and convert the solar energy, for example, into usable energy. In one embodiment, flexible solar panel 4 converts the solar energy into electricity that can be stored in energy storage unit 24 and can be suitable for powering or use with accessories 8. In another embodiment, flexible solar panel 4 converts solar energy into electricity with an appropriate wattage and voltage for storage in energy storage unit 24 and can be suitable for powering or use with accessories 8. Rays 10 can be from other sources of energy, such as a light bulb.

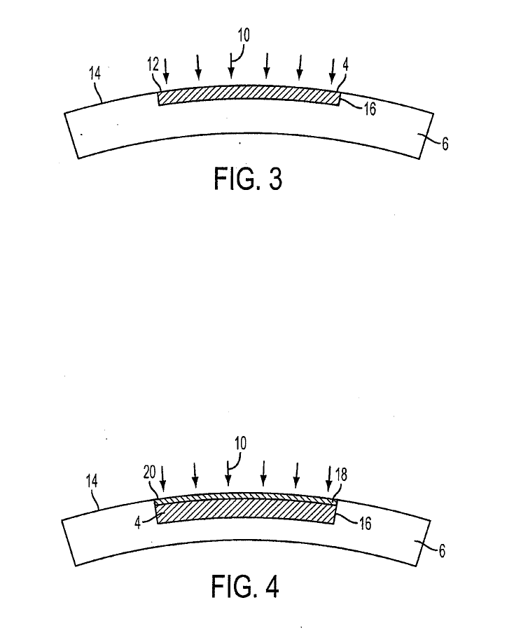

FIG. 2 is a perspective view of an exemplary solar panel 4 embedded into or on a dashboard or an instrument panel 6 of automobile 2 according to an embodiment of the present invention. FIG. 3 is a cross-sectional view of FIG. 2 along line A-A showing flexible solar panel 4 embedded or placed into instrument panel 6 according to an embodiment of the present invention. As shown in FIG. 3, instrument panel 6 includes a recessed portion 16. Flexible solar panel 4 is located within recessed portion 16 such that a top portion 12 of flexible solar panel 4 is flush with a top portion 14 of instrument panel 6.

Flexible solar panel 4 can be made of a material that is flexible enough to mold to the curvatures of instrument panel 6 and also be resistant to shattering. For example, flexible solar panel 4 can be made of a material that is resistant to shattering upon high impacts such as an automobile accident. In one embodiment, flexible solar panel 4 can have a durometer between 20 durometer Shore A to 70 durometer Shore A.

Flexible solar panel 4 may be made of a material that allows vehicle 2 to earn three out of five stars in the National Highway Traffic Safety Administration (“NHTSA”) frontal crash driver rating, or where there is a 21% to 35% chance of serious injury to the driver in a head-on collision in which each vehicle is going 35 mph. In another embodiment, flexible solar panel 4 is made of a material that allows vehicle 2 to earn four out of five stars in the NHTSA frontal crash driver rating, or where there is 11% to 20% chance of serious injury to the driver in a head-on collision in which each vehicle is going 35 mph. In yet another embodiment, flexible solar panel 4 is made of a material that allows vehicle 2 to earn five out of five stars in the NHTSA frontal crash driver rating where there is a 10% chance of serious injury to the driver in a head-on collision in which each vehicle is going 35 mph. In still yet another embodiment, flexible solar panel 4 is made of a material to meet an appropriate safety standard given by an agency such as a federal, state, governmental, and/or regulatory agency.

In one embodiment, flexible solar panel 4 is made of a triple junction amorphous silicon material. In another embodiment, flexible solar panel 4 includes a flexible plastic backing with silicon deposited on top of the flexible plastic backing. In yet another embodiment, flexible solar panel 4 is made of nano-sized semiconductor crystals such as titanium dioxide. In one embodiment, flexible solar panel 4 can have a thickness of about 10 millimeters (mm) or less. By having flexible solar panel 4 have a thickness of about 10 mm or less, the weight of flexible solar panel 4 can advantageously be reduced. Furthermore, a thickness of about 10 mm or less increases the flexibility of flexible solar panel 4.

FIG. 4 is a cross-sectional view of FIG. 2 along line A-A showing a translucent thin film 18 placed on top of flexible solar panel 4 such that both layers are within recessed portion 16 of instrument panel 6 according to an embodiment of the present invention. That is, translucent thin film 18 is placed on top of flexible solar panel 4 such that a top portion 20 of translucent thin film 18 is flush with top portion 14 of instrument panel 6. Translucent thin film 18 provides a protective coating or cover over flexible solar panel 4 to reduce glare and reflections onto a windshield of vehicle 2 and to prevent scratches or other damage from occurring on flexible solar panel 4. Translucent thin film 18 can also be flexible and resistant to shattering upon high impacts. Translucent thin film 18 can also be made of a material that meets a safety standard for a federal, state, governmental, and/or regulatory agency.

Referring back to FIG. 1, energy storage unit 24 is connected to flexible solar panel 4 through connection 30, control unit 28 through connection 36, and accessories 8 through connection 32. Energy storage unit 24 stores energy received from flexible solar panel 4. Also, energy storage unit 24 can convert energy received from flexible solar panel 4 into an appropriate wattage and voltage for use with accessories 8. Energy storage unit 24 can be, for example, a battery, a super capacitor, a conventional capacitor, a hybrid battery, and/or fuel cells.

Accessories 8 are connected to energy storage unit 24 through connection 32 and control unit 28 through energy storage unit 24. Accessories 8 can be, for example, one or more headlights, clocks, automatic car opening and closing systems, car alarms, audio and video systems, global positioning systems (“GPS”), radar detectors, portable music players, computers, various electronic devices which can be connected to a DC socket within automobile 2, fans, etc. Energy storage unit 24 can be a relatively light weight device. In one embodiment, energy storage unit 24 weighs less than 10 kilograms (kg). In various embodiments, energy storage unit 24 may weigh less than 5 kg, 2 kg or 1 kg.

Accessories 8 can be a battery for automobile 2, which is an electric vehicle. This can advantageously increase the distance that the electric vehicle travels without being plugged into an outlet for charging.

In another embodiment, accessories 8 can be a battery for automobile 2, which is a hybrid vehicle. This can further improve the efficiency of the hybrid vehicle and reduce the amount of liquid fuel consumed. Thus, the present invention may advantageously increase the miles per gallon that automobile 2 gets out of its liquid fuel such as gasoline.

Furthermore, an ignition system (not shown) can also be part of accessories 8. If the ignition system is part of accessories 8, then a traditional battery may not be needed in addition to energy storage unit 24 or a weight of the traditional battery can be reduced. This advantageously can reduce a weight of automobile 2 by 10 kg, 20 kg, 30 kg, or more. Reducing the weight of automobile 2 can be more efficient since automobile 2 will have to transport less weight. With energy prices and energy efficiency requirements potentially increasing this can have a significant impact on the viability of automobile 2.

Furthermore, traditional batteries are generally placed in a front compartment of automobile 2. By removing or reducing the weight of traditional batteries in automobile 2, a better weight distribution can be achieved. For example, a weight distribution that is closer to a 50/50 weight distribution between the front of automobile 2 and a rear of automobile 2 can be achieved in automobile 2. A 50/50 weight distribution can also improve performance and efficiency of automobile 2.

In addition, since energy storage unit 24 receives energy from flexible solar panel 4, a risk of automobile 2 being unable to start due to a lack of energy can be reduced, especially during day time where there is ample lighting. That is because flexible solar panel 4 can provide energy to energy storage unit 24 without automobile 2 having its engine on or being active. Thus, energy storage unit 24 can be recharged or replenished.

In one embodiment, energy storage unit 24 can also have its energy level recharged or replenished through a feedback system connected to a motor of automobile 2; in addition to having its energy level replenished by flexible solar panel 4. In another embodiment, energy storage unit 24 can also have its energy level recharged or replenished through a feedback system connected to brakes of automobile 2.

Optional control unit 28 is connected to flexible solar panel 4 through connection 34, energy storage unit 24 through connection 36, and accessories 8 through connection 38. In one embodiment, control unit 28 monitors an energy output from flexible solar panel 4, an amount of energy stored in energy storage unit 24 and an energy consumption level of accessories 8. Control unit 28 can automatically configure all or a number of accessories 8 to draw energy from energy storage unit 24. Control unit 28 can also allow a user of automobile 2 to select which accessories 8 to draw energy from energy storage unit 24.

Control unit 28 can determine, based on the energy consumption level of accessories 8, the amount of energy stored in energy storage unit 24, the energy output from flexible solar panel 4, and whether the amount of energy stored in energy storage unit 24 is increasing or decreasing. When the amount of energy stored in energy storage unit 24 is decreasing, control unit 28 can determine an amount of time left before the energy stored in energy storage unit 24 is depleted. In one embodiment, control unit 28 provides a warning to a user of automobile 2 when the energy will be depleted in energy storage unit 24 within a predetermined period of time or a number of miles.

In another embodiment, control unit 28 can automatically deactivate one or more accessories 8 when the amount of energy stored in energy storage unit 24 is below a predetermined amount of energy. In yet another embodiment, control unit 28 automatically deactivates all accessories 8 when the amount of energy stored in energy storage unit 24 is below a predetermined amount of energy. This can be particularly beneficial, for example, when a user is attempting to start a car. If the user has accidentally left one accessory 8 on, which drains energy, such as the headlights, and there is not enough sunlight to fully sustain the energy consumption of the headlights, control unit 28 can automatically shut off the headlights and preserve enough energy within energy storage unit 24 to start automobile 2 through the ignition system immediately or within a reasonable amount of time.

In operation, sun 22 transmits solar energy to flexible solar panel 4 through rays 10. Flexible solar panel 4 receives the solar energy through rays 10 and converts the solar energy into usable energy that is stored in energy storage unit 24 and utilized by accessories 8 such as electricity with an appropriate wattage and voltage. In one embodiment, the voltage is approximately 12 volts. Flexible solar panel 4 transmits the usable energy through connection 30 to energy storage unit 24. Energy storage unit 24 stores the usable energy. Accessories 8 draw the usable energy stored by energy storage unit 24 to operate through connection 32.

Control unit 28 monitors the energy output from flexible solar panel 4, the amount of energy stored in energy storage unit 24 and the energy consumption level of each accessory 8. Control unit 28 can determine which accessory 8 is using the most energy and the driver or user of automobile 2 can be notified (e.g., via a display screen) which accessory 8 is consuming the most energy so the driver or user can turn off the accessory 8 that is using the most energy. Control unit 28 can display appropriate warnings to the user of automobile 2 based on the amount of energy stored in energy storage unit 24 and the energy consumption level of accessories 8. Control unit 28 can also control whether one or more accessories 8 are turned off or on.

If there is an accident, flexible solar panel 4 can bend and contort itself in response to a high impact. Furthermore, by being flexible, flexible solar panel 4 can resist shattering. This can reduce or eliminate the number of projectiles that flexible solar panel 4 emits. By reducing the number of projectiles that flexible solar panel 4 emits, it is contemplated that this could produce a safer environment for the user of automobile 2 since projectiles could impact the user at a high velocity causing harm to the user. Furthermore, the projectiles can get into sensitive areas of the user such as the user's eye, and cause serious damage to the user's eye. Furthermore, even after the projectiles are in a resting position, they could be sharp and thus the projectiles could form a hazardous zone around the user and also any rescue workers attempting to rescue the user. Thus, flexible solar panel 4 could improve the safety of automobile 2.

Furthermore, by being shatter resistant, it is contemplated that the necessity to replace flexible solar panel 4 after an accident has occurred could be reduced. This could increase the longevity of flexible solar panel 4 and reduce the cost of operation and/or repair of automobile 2.

In one embodiment, flexible solar panel 4 is not formed around an area where an airbag is to be deployed from instrument panel 6 such as in a passenger area as opposed to a driver area. For example, flexible solar panel 4 can have a hole in a center where an airbag is to be deployed. This can reduce the probability that flexible solar panel 4 can be damaged and/or hamper the ability of airbag 4 to be deployed. In another embodiment, when the airbag is deployed, flexible solar panel 4 can form two or more panels such that the airbag can be deployed between the two or more panels. In yet another embodiment, the airbag can be deployed such that it lifts a portion of instrument panel 6 along with flexible solar panel 4.

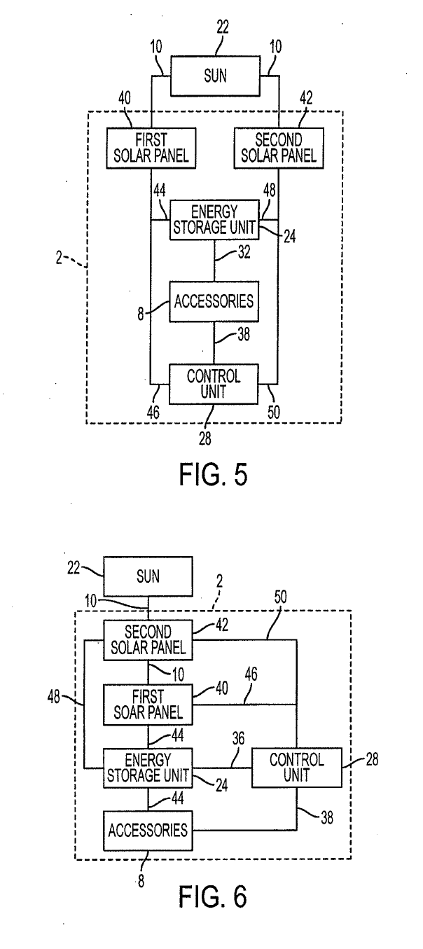

FIG. 5 is a block diagram of a vehicle interior solar system according to an embodiment of the present invention. As seen in FIG. 5, the present invention can include two solar panels, first solar panel 40 and second solar panel 42. First solar panel 40 and second solar panel 42 can be made of the same material as flexible solar panel 4 and can also be flexible solar panels. First solar panel 40 and second solar panel 42 can be made of the same material as each other or different materials from each other.

First solar panel 40 and second solar panel 42 are connected to energy storage unit 24 through connections 44 and 48, respectively. First solar panel 40 and second solar panel 42 are connected to control unit 28 through connections 46 and 50, respectively. In one embodiment, first solar panel 40 is located in a first location and second solar panel 42 is located in a second location. In another embodiment, first solar panel 40 is located on instrument panel 6, while second solar panel 42 is located on a rear of automobile 2 in a parcel shelf (not shown). Control unit 28 can monitor the energy output from first solar panel 40 and second solar panel 42, the amount of energy stored in energy storage unit 24 and the energy consumption level of accessories 8. Control unit 28 can display appropriate warnings to the user of automobile 2 based on the amount of energy stored in energy storage unit 24 and the energy consumption level of accessories 8. Control unit 28 can also control whether one or more accessories 8 are turned off or on.

FIG. 6 is a block diagram of a vehicle interior solar system according to an embodiment of the present invention. In FIG. 6, second solar panel 42 is located between first solar panel 40 and sun 22. First solar panel 40 can be made of the same material as flexible solar panel 4 and can also be a flexible solar panel. Second solar panel 40 can be made of a translucent and/or semi-translucent material. Second solar panel 40 can also be a flexible solar panel. In addition, second solar panel 40 can comprise, for example, translucent thermoplastic resin, such as polycarbonate. Second solar panel 40 can also comprise, for example, a multi-walled translucent polycarbonate sheet material. In one embodiment, second solar panel 40 is a dye-infused, translucent solar cell integrated into a translucent material such as a window. In another embodiment, second solar panel 40 comprises a nano-particulate porous film formed on a conductive substrate, a layer of dye, a transparent conductor, and an electrolyte located between the layer of dye and the conductive substrate.

Referring to FIGS. 6, 7, and 8, sun 22 can emit rays 10 onto second solar panel 10. Some of the solar energy from rays 10 can be absorbed by second solar panel 42. Rays 10 can flow through second solar panel 42 onto first solar panel 40 where first solar panel 40 can receive the remaining rays 10 and solar energy. This can improve the amount of solar energy absorbed and also improve the amount of usable energy generated as a result of the absorption of solar energy.

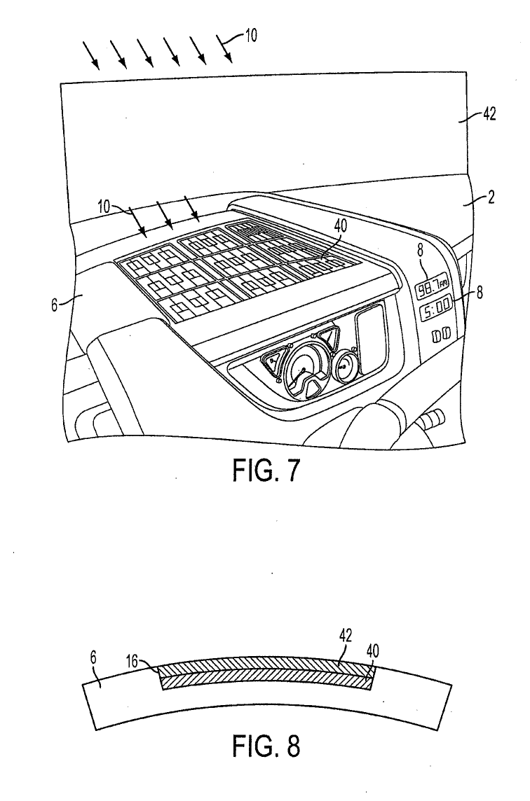

FIG. 7 is a perspective view of an exemplary solar panel embedded into or on a dashboard or an instrument panel of automobile according to an embodiment of the present invention. As seen in FIG. 7, in one embodiment, second solar panel 42 is a window of automobile 2. Second solar panel 42 can be made of a translucent and/or semi-translucent material sufficient to allow the user of automobile 2 to have adequate visibility of a road and/or her surroundings. Since automobiles in general utilize windows, better space and energy efficiency may be achieved by replacing conventional windows or windshields with second solar panel 42. Furthermore, the use of second solar panel 42 may be advantageous in reducing an amount of rays 10 that is visible to the user of automobile 2. This can advantageously reduce an amount of glare that the user of automobile 2 receives thus improving the visibility for the user.

FIG. 8 is a cross-sectional view of two solar panels where one is on top of the other according to an embodiment of the present invention. As shown in FIG. 8, second solar panel 42 can be placed on top of first solar panel 40. This can improve the amount of solar energy captured by the present invention since instead of only one solar panel, there are now two solar panels used to capture the solar energy. This can increase an amount of solar energy captured without increasing the amount of space required on instrument panel 6 since second solar panel 42 is placed on top of first solar panel 40. This is advantageous since rising fuel costs may require automobile 2 and solar panels to be limited in size.

The previous description of the disclosed examples is provided to enable any person of ordinary skill in the art to make or use the disclosed methods and apparatus. Various modifications to these examples will be readily apparent to those skilled in the art, and the principles defined herein may be applied to other examples without departing from the spirit or scope of the disclosed method and apparatus. The described embodiments are to be considered in all respects only as illustrative and not restrictive and the scope of the invention is, therefore, indicated by the appended claims rather than by the foregoing description. All changes which come within the meaning and range of equivalency of the claims are to be embraced within their scope.

What is claimed is:

1. An automobile comprising:
an instrument panel including an instrument panel top surface, the instrument panel top surface including a portion defining a recessed portion;
a first flexible solar panel located within the recessed portion;
an energy storage unit connected to the first flexible solar panel and receiving electricity from the first flexible solar panel; and
an electronic component connected to the energy storage unit.

2. The automobile of claim 1 wherein the first flexible solar panel is resistant to shattering.

3. The automobile of claim 2 wherein the first flexible solar panel is resistant to shattering when an accident occurs.

4. The automobile of claim 3 wherein the first flexible solar panel includes a first flexible solar panel top surface connected to the instrument panel top surface, and the first flexible solar panel top surface is substantially flush with the instrument panel top surface where the first flexible solar panel top surface and the instrument panel top surface are connected.

5. The automobile of claim 3 further comprising a translucent thin film on top of the first flexible solar panel.

6. The automobile of claim 5 wherein the translucent thin film includes a translucent thin film top surface connected to the instrument top panel surface, and the translucent thin film top surface is substantially flush with the instrument panel top surface where the translucent thin film and the instrument panel top surface are connected.

7. The automobile of claim 4 further comprising:
a parcel shelf, and
a second flexible solar panel resistant to shattering located at the parcel shelf and connected to the energy storage unit.

8. The automobile of claim 7 wherein the first flexible solar panel and the second flexible solar panel are comprised of a triple junction amorphous silicon.

9. The automobile of claim 8 further comprising an ignition system connected to the energy storage unit.

10. The automobile of claim 9 further comprising a transparent solar panel connected to the energy storage unit.

11. The automobile of claim 10 wherein the transparent solar panel is located between the first flexible solar panel and a solar energy source.

12. The automobile of claim 10 wherein a thickness of the first flexible solar panel and the second flexible solar panel is less than 10 mm.

13. An automobile comprising:
an instrument panel including an instrument panel top surface, the instrument panel top surface including a portion defining a recessed portion;
a first flexible solar panel located within the recessed portion, the first flexible solar panel including a first flexible solar panel top surface and being resistant to shattering when an accident occurs, wherein the first flexible solar panel top surface is connected to the instrument panel top surface, and the first flexible solar panel top surface is substantially flush with the instrument panel top surface where the first flexible solar panel top surface and the instrument panel top surface are connected;
an energy storage unit connected to the first flexible solar panel and receiving electricity from the first flexible solar panel; and
an electronic component connected to the energy storage unit.

14. The automobile of claim 13 further comprising:
a parcel shelf; and
a second flexible solar panel resistant to shattering located at the parcel shelf and connected to the energy storage unit, wherein the first flexible solar panel and the second flexible solar panel are comprised of a triple junction amorphous silicon.

15. The automobile of claim 14 wherein a thickness of the first flexible solar panel and the second flexible solar panel is less than 10 mm.

16. The automobile of claim 13 further comprising an ignition system connected to the energy storage unit.

17. The automobile of claim 13 further comprising a transparent solar panel connected to the energy storage unit, the transparent solar panel located between the first flexible solar panel and a solar energy source.

18. An automobile comprising:
an instrument panel including an instrument panel top surface, the instrument panel top surface including a portion defining a recessed portion;
a parcel shelf;
a first flexible solar panel located within the recessed portion, the first flexible solar panel including a first flexible solar panel top surface, having a thickness less than 10 mm, and being resistant to shattering when an accident occurs, wherein the first flexible solar panel top surface is connected to the instrument panel top surface, and the first flexible solar panel top surface is substantially flush with the instrument panel top surface where the first flexible solar panel top surface and the instrument panel top surface are connected;
a second flexible solar panel resistant to shattering located at the parcel shelf and having a thickness less than 10 mm;
an energy storage unit connected to the first flexible solar panel and the second flexible solar panel and receiving electricity from the first flexible solar panel and the second flexible solar panel;
an ignition system connected to the energy storage unit; and
an electronic component connected to the energy storage unit.

19. The automobile of claim 18 further comprising a transparent solar panel connected to the energy storage unit, the transparent solar panel located between the first flexible solar panel and a solar energy source.

20. The automobile of claim 18 wherein the first flexible solar panel and the second flexible solar panel are comprised of a triple junction amorphous silicon.
